(19) United States
(12) Patent Application Publication
(10) Pub. No.: US 2026/0114106 A1
(43) Pub. Date: Apr. 23, 2026

(54) DISPLAY DEVICE

(71) Applicant: LG Display Co., Ltd., Seoul (KR)

(72) Inventor: Binn KIM, Paju-si (KR)

(73) Assignee: LG Display Co., Ltd., Seoul (KR)

(21) Appl. No.: 19/299,099

(22) Filed: Aug. 13, 2025

(30) Foreign Application Priority Data
Oct. 23, 2024 (KR) 10-2024-0145945

(51) Int. Cl. H10H 29/855; H10H 29/49

(52) U.S. Cl. CPC H10H 29/8552; H10H 29/49

(57) ABSTRACT

A display device includes a substrate including an emission area and a non-emission area, a driving element formed over the substrate, a first connection electrode connected to the driving element, a light-emitting element connected to the first connection electrode, and a second connection electrode formed over the light-emitting layer, wherein the second connection electrode includes an antireflection area corresponding to the non-emission area, and wherein a first portion of the second connection electrode includes a plurality of layers in the antireflection area to distinguish the emission area and the non-emission area, thereby providing a low-cost and high-quality display device.

### CROSS-REFERENCE TO RELATED APPLICATION

The present application claims priority to Korean Patent Application No. 10-2024-0145945 filed in the Republic of Korea on Oct. 23, 2024, the entire contents of which are hereby expressly incorporated by reference into the present application.

### BACKGROUND

### Technical Field

The present disclosure relates to a display device.

### Discussion of the Related Art

A display device may include an emission area and a non-emission area, and may also include a plurality of pixels each including a light-emitting element and various circuit elements for driving the light-emitting element. In this case, when external light is reflected by various material layers constituting the light-emitting element and the circuit elements, a problem may occur in which a user using the display device has difficulty identifying information displayed on the display device due to the external light.

A related art display device can effectively reduce the reflectance of the external light by using a polarizing plate or forming a separate black antireflection layer to reduce the reflectance of the external light. However, the use of expensive polarizing plate and the formation of the separate antireflection layer can increase the manufacturing costs of the display device.

### SUMMARY

The related art display device has problems in that the cost increases and the structure becomes complicated because additional optical layers have to be formed to prevent degradation of quality in a non-powered state due to the rainbow mura phenomenon caused by light reflected from the external light and degradation of image quality of the display device due to the reflected light. In addition, the display technology requires technology that can be implemented even in small pixels in order to respond to higher resolution, and also requires lower reflectance with respect to the reflection of the external light. Accordingly, the present disclosure provides a display device that can be operated at a lower cost and with lower power by implementing low reflectance without using a polarizing plate and a separate antireflection layer.

An aspect of the present disclosure is to provide a display device having an electrode structure that reduces the reflectance for the reflected external light.

Accordingly, embodiments of the present disclosure are directed to a display device that substantially obviates one or more of the problems due to limitations and disadvantages of the related art.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a substrate including an emission area and a non-emission area, a driving element formed over the substrate, a first connection electrode connected to the driving element, a light-emitting element connected to the first connection electrode, and a second connection electrode formed over the light-emitting layer, wherein the second connection electrode may include an antireflection area corresponding to the non-emission area, and wherein a first portion of the second connection electrode may include a plurality of layers in the antireflection area to distinguish the emission area and the non-emission area.

In another aspect, a display device comprises a substrate including a display area, a driving element formed over the substrate, a first connection electrode connected to the driving element, a light-emitting element connected to the first connection electrode, and a second connection electrode connected to the light-emitting element and distinguishing an emission area and a non-emission area.

The second connection electrode can be formed over the light-emitting element and connected to the light-emitting element.

The second connection electrode can include an antireflection area appearing black in the non-emission area, and can include a plurality of layers in the antireflection area.

The second connection electrode can include a transparent conductive material, and the second connection electrode can be configured as a single layer of the transparent conductive material in the emission area.

In the non-emission area, the second connection electrode can include an antireflection layer composed of multiple layers having conductivity, and the transparent conductive material of the emission area can extend and disposed under the antireflection layer composed of the multiple layers.

The antireflection layer can appear black by minimizing reflection of external light by light offset due to difference in refractive index between the multiple layers. The antireflection layer can include a double layer of semitransparent film-reflective film or a triple layer of semitransparent film-transparent film-reflective film in the direction from the outside of the display device toward the substrate.

The semitransparent film of the antireflection layer can be an oxide or nitride of one of chromium, molybdenum, titanium, and aluminum, and the reflective film can include one of copper, aluminum, silver, and gold.

In other embodiments of the present disclosure, the transparent conductive material can be provided in the emission area, and the antireflection layer can be provided in the non-emission area and disposed on the transparent conductive material extending from the emission area. The antireflection layer can be positioned lower than the top of the light-emitting element and be disposed to surround the light-emitting element.

The light-emitting layer of the light-emitting element can be positioned higher than the antireflection layer. The top of the planarization layer surrounding the light-emitting element can be positioned lower than the top of the light-emitting element.

Other embodiments of the present disclosure are to provide a display device in which the inorganic insulation layer can be disposed on and be in contact with the second connection electrode in the emission area, and an inorganic insulation layer may not be provided in the non-emission area.

In the non-emission area without an inorganic insulation layer, the second connection electrode can include the antireflection layer on the transparent conductive material extending from the emission area.

The transparent conductive material of the emission area where the inorganic insulation layer is disposed and the antireflection layer of the non-emission area can have the same components. The antireflection layer of the non-emission area can be a discoloration layer that changes to black depending on the component ratio different from that of the transparent conductive material of the emission area through the process. The different component ratios can be component ratios of indium and oxygen.

The antireflection layer with different component ratios of the non-emission area can appear black.

The distinction of the second connection electrode between the emission area and the non-emission area can be formed through the following steps.

A driving element can be formed over a substrate. A first connection electrode can be formed over and connected to the driving element. A light-emitting element can be formed over the first connection electrode. A second connection electrode formed of a transparent conductive material including indium can be deposited over the light-emitting element, and an inorganic insulation layer can be formed only in the emission area on the deposited second connection electrode. An etching process such as a plasma process containing hydrogen can be performed on the second connection electrode of the non-emission area using the inorganic insulation layer as a mask, so that the second connection electrode of the non-emission area can change from a transparent color to black.

The upper surface of the inorganic insulation layer of the emission area can have a flat shape.

In other embodiments, the upper surface of the inorganic insulation layer of the emission area can include a lens shape. The lens shape can include a first lens and second lenses having a smaller size than the first lens. The first lens can be disposed in a center of the emission area, and the second lenses can surround the first lens.

The lens shape can be configured to be symmetrical with respect to the center of the emission area.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles of the disclosure. In the drawings:

FIG. 1 is a view showing a schematic configuration of a display device according to an embodiment of the present disclosure;

FIG. 2 is a cross-sectional view illustrating each sub-pixel of a display panel of a display device according to a first embodiment of the present disclosure;

FIG. 3A and FIG. 3B are views showing effects of reflected light according to a second connection electrode in an emission area and a non-emission area according to an embodiment of the present disclosure;

FIG. 4 is a cross-sectional view illustrating each sub-pixel of a display panel of a display device according to a second embodiment of the present disclosure;

FIG. 5 is a cross-sectional view illustrating each sub-pixel of a display panel of a display device according to a third embodiment of the present disclosure; and

FIG. 6 is a cross-sectional view illustrating each sub-pixel of a display panel of a display device according to a fourth embodiment of the present disclosure.

### DETAILED DESCRIPTION

Hereinafter, some embodiments of the present disclosure will be described in detail with reference to exemplary drawings. When adding reference numerals to components of each drawing, the same components may have the same numerals as much as possible even if they are shown in different drawings. In addition, when describing the present disclosure, if it is determined that a specific description of a related known configuration or function may obscure the gist of the present disclosure, the detailed description may be omitted. When “includes,” “has,” “consists of,” etc. are used in this specification, other parts may be added unless “only” is used. When a component is expressed in singular, it may include a case where it includes plural unless there is a special explicit description.

In addition, when describing the components of the present disclosure, terms such as first, second, A, B, (a), (b), etc. may be used. These terms are only intended to distinguish the components from other components, and the nature, order, sequence, or number of the components is not limited by the terms.

In the description of the positional relationship of the components, when it is described that two or more components are “connected” or “coupled” etc., it should be understood that the two or more components may be directly “connected” or “coupled”, but the two or more components and another component may be further “interposed” to be “connected” or “coupled”, Here, the other component may be included in one or more of the two or more components that are “connected” or “coupled” to each other.

In the description of the temporal flow relationship related to components, operation methods, or manufacturing methods, for example, when the temporal chronological relationship or the flow chronological relationship is described as “after˜,” “following˜,” “next to˜,” or “before ˜,” it may also include cases where it is not continuous, unless “right away” or “directly” is used.

On the other hand, when a numerical value or corresponding information (e.g., level, etc.) for a component is mentioned, even if there is no separate explicit description, the numerical value or corresponding information may be interpreted as including an error range that may occur due to various factors (e.g., process factors, internal or external impact, noise, etc.).

Hereinafter, various embodiments of the present disclosure will be described in detail with reference to the attached drawings.

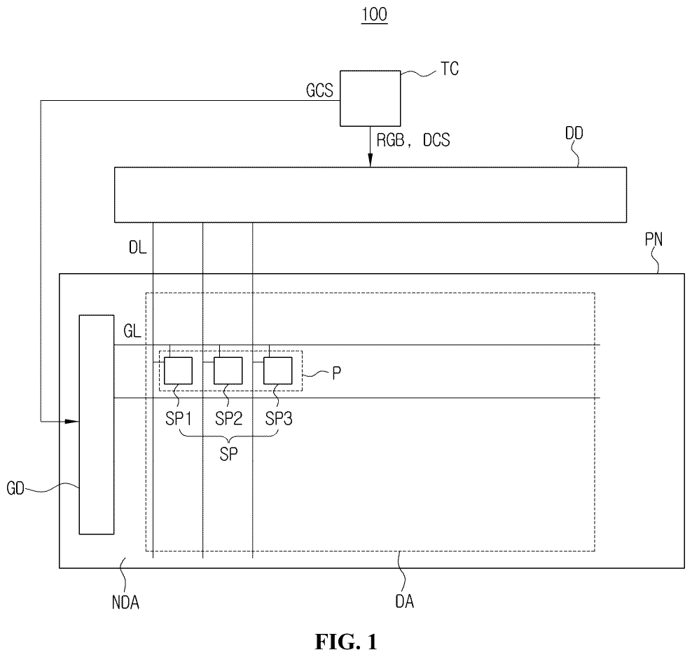

FIG. 1 is a view showing a schematic configuration of a display device according to an embodiment of the present disclosure. The display device may be a micro LED (light-emitting diode) display device or a mini LED display device. However, embodiments of the present disclosure are not limited thereto, and in other embodiments, for example, the display device may be an organic light-emitting diode (OLED) display device.

In FIG. 1, a display device 100 according to an embodiment of the present disclosure may include a timing controller TC, a data driver DD, a gate driver GD, and a display panel PN.

The timing controller TC may generate image data RGB, a data control signal DCS, and a gate control signal GCS using a plurality of timing signals, such as an image signal, a data enable signal, a horizontal synchronization signal, a vertical synchronization signal, and a clock, transmitted from an external system such as a graphic card or a TV system. Then, the timing controller TC may transmit the generated image data RGB and the generated data control signal DCS to the data driver DD and may transmit the generated gate control signal GCS to the gate driver GD.

The data driver DD may generate a data signal (data voltage) using the image data RGB and the data control signal DCS transmitted from the timing controller TC and may apply the generated data signal to a data line DL of the display panel PN.

The gate driver GD may generate a gate signal using the gate control signal GCS transmitted from the timing controller TC and may apply the generated gate signal to a gate line GL of the display panel PN.

Here, the gate driver GD may be a gate-in-panel (GIP) type formed together on a substrate of the display panel PN on which the gate line GL, the data line DL, and a pixel P are formed and may be disposed in a non-display area NDA.

In the embodiment of FIG. 1, the gate driver GD may be disposed on one side of the display panel PN, but in other embodiments, two gate drivers may be disposed on both sides of the display panel PN, respectively.

The display panel PN may include a display area DA at its center and a non-display area NDA surrounding the display area DA and may display an image using the gate signal and the data signal. The display panel PN may include a plurality of pixel P, a plurality of gate lines GL, and a plurality of data lines DL disposed in the display area DA.

Each of the plurality of pixels P may include sub-pixels SP comprising first, second, and third sub-pixels SP1, SP2, and SP3. The gate lines GL and the data lines DL may cross each other to define the sub-pixels SP, and each sub-pixel SP may be connected to the gate line GL and the data line DL corresponding thereto. For example, the first, second, and third sub-pixels SP1, SP2, and SP3 may correspond to first, second, and third colors, respectively, and the first, second, and third colors may be red, green, and blue, respectively.

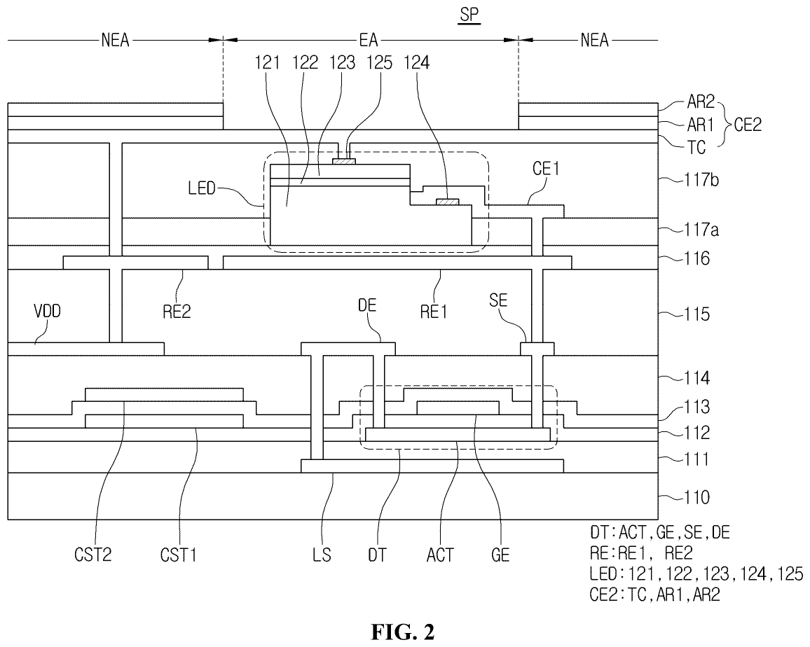

Each sub-pixel SP may include a plurality of transistors, such as a switching transistor, a driving transistor DT of FIG. 2, and a sensing transistor, a storage capacitor, and a light-emitting diode LED of FIG. 2.

FIG. 2 is a cross-sectional view illustrating each sub-pixel of a display panel of a display device according to a first embodiment of the present disclosure and will be described with reference to FIG. 1 together.

In FIG. 2, a light-shielding pattern LS may be provided in each sub-pixel SP on a substrate 110, and a buffer layer 111 may be provided on the light-shielding pattern LS substantially all over the substrate 110. The substrate 110 may include an emission area EA and a non-emission area NEA.

The light-shielding pattern LS may serve to block light incident from the bottom of the substrate 110. For example, the light-shielding pattern LS may be a single layer or multiple layers of a metal material such as one of molybdenum (Mo), aluminum (Al), chromium (Cr), gold (Au), titanium (Ti), nickel (Ni), neodymium (Nd), and copper (Cu) or an alloy thereof.

The buffer layer 111 may serve to block moisture or oxygen penetrating from the outside. For example, the buffer layer 111 may be a single layer or multiple layers of an inorganic insulating material such as silicon oxide (SiO₂) or silicon nitride (SiNx).

A semiconductor layer ACT may be provided on the buffer layer 111 corresponding to the light-shielding pattern LS, and a gate insulation layer 112 may be provided on the semiconductor layer ACT substantially all over the substrate 110.

The semiconductor layer ACT may include a channel region not doped with impurities in the center and a source region and a drain region doped with impurities on both sides of the channel region. For example, the semiconductor layer ACT may be formed of a polycrystalline semiconductor material such as polycrystalline silicon, or an oxide semiconductor material such as indium gallium zinc oxide (IGZO), zinc oxide (ZnO), tin oxide (SnO₂), copper oxide (Cu₂O), nickel oxide (NiO), indium tin zinc oxide (ITZO), and indium aluminum zinc oxide (IAZO).

For example, the gate insulation layer 112 may be a single layer or multiple layers of an inorganic insulating material such as silicon oxide (SiO₂) or silicon nitride (SiNx).

A gate electrode GE may be provided on the gate insulation layer 112 corresponding to the channel region, a first capacitor electrode CST1 may be provided on the gate insulation layer 112 and be spaced apart from the gate electrode GE, and a first interlayer insulation layer 113 may be provided on the gate electrode GE and the first capacitor electrode CST1 substantially all over the substrate 110.

The gate electrode GE and the first capacitor electrode CST1 may be formed of the same material and on the same layer. For example, the gate electrode GE and the first capacitor electrode CST1 may be a single layer or multiple layers of a metal material such as one of molybdenum (Mo), aluminum (Al), chromium (Cr), gold (Au), titanium (Ti), nickel (Ni), neodymium (Nd), and copper (Cu) or an alloy thereof.

For example, the first interlayer insulation layer 113 may be a single layer or multiple layers of an inorganic insulating material such as silicon oxide (SiO₂) or silicon nitride (SiNx).

A second capacitor electrode CST2 may be provided on the first interlayer insulation layer 113 corresponding to the first capacitor electrode CST1, and a second interlayer insulation layer 114 may be provided on the second capacitor electrode CST2 substantially all over the substrate 110.

For example, the second capacitor electrode CST2 may be a single layer or multiple layers of a metal material such as one of molybdenum (Mo), aluminum (Al), chromium (Cr), gold (Au), titanium (Ti), nickel (Ni), neodymium (Nd), and copper (Cu) or an alloy thereof.

For example, the second interlayer insulation layer 114 may be a single layer or multiple layers of an inorganic insulating material such as silicon oxide (SiO₂) or silicon nitride (SiNx).

The first capacitor electrode CST1, the first interlayer insulation layer 113, and the second capacitor electrode CST2 can constitute a storage capacitor.

A source electrode SE and a drain electrode DE may be provided on the second interlayer insulation layer 114 and may be spaced apart from each other.

The source electrode SE and the drain electrode DE may be connected to the source region and the drain region of the semiconductor layer ACT through contact holes of the second interlayer insulation layer 114, the first interlayer insulation layer 113, and the gate insulation layer 112, respectively. The drain electrode DE may be connected to the light-shielding pattern LS through a contact hole of the second interlayer insulation layer 114, the first interlayer insulation layer 113, the gate insulation layer 112, and the buffer layer 111.

The source electrode SE and the drain electrode DE may be formed of the same material and on the same layer. For example, the source electrode SE and the drain electrode DE may be a single layer or multiple layers of a metal material such as one of molybdenum (Mo), aluminum (Al), chromium (Cr), gold (Au), titanium (Ti), nickel (Ni), neodymium (Nd), and copper (Cu) or an alloy thereof.

The semiconductor layer ACT, the gate electrode GE, the source electrode SE, and the drain electrode DE can constitute a driving element, i.e., a driving transistor DT.

A power line VDD may be provided on the second interlayer insulation layer 114. The power line VDD may be electrically connected to a first light-emitting element LED together with the driving transistor DT to cause the first light-emitting element LED to emit light. The power line VDD may be formed of the same material and on the same layer as the source electrode SE and the drain electrode DE. For example, the power line VDD may be a single layer or multiple layers of a metal material such as one of molybdenum (Mo), aluminum (Al), chromium (Cr), gold (Au), titanium (Ti), nickel (Ni), neodymium (Nd), and copper (Cu) or an alloy thereof, but embodiments of the present disclosure are not limited thereto.

An overcoat layer 115 may be provided on the driving transistor DT and the power line VDD. The overcoat layer 115 may flatten the upper surface of the substrate 110 on which the driving transistor DT is disposed. The overcoat layer 115 may be a single layer or multiple layers and, for example, may be formed of photoresist or acrylic-based organic material, but is not limited thereto.

A plurality of reflection electrodes RE may be provided on the overcoat layer 115 and may be spaced apart from each other. The plurality of reflection electrodes RE may electrically connect the first light-emitting element LED to the power line VDD and the driving transistor DT and may function as reflectors that reflect light emitted from the first light-emitting element LED toward the upper portion of the first light-emitting element LED. The plurality of reflection electrodes RE may be formed of a conductive material having relatively high reflection characteristics, and may reflect light emitting from the first light-emitting element LED toward the upper portion of the first light-emitting element LED.

The plurality of reflection electrodes RE may include a first reflection electrode RE1 and a second reflection electrode RE2. The first reflection electrode RE1 may electrically connect the driving transistor DT and the first light-emitting element LED. The first reflection electrode RE1 may be connected to the source electrode SE or the drain electrode DE of the driving transistor DT through a contact hole formed in the overcoat layer 115. In addition, the first reflection electrode RE1 may be electrically connected to a first electrode 124 of the first light-emitting element LED through a first connection electrode CE1.

The second reflection electrode RE2 may electrically connect the power line VDD and the first light-emitting element LED. The second reflection electrode RE2 may be connected to the power line VDD through a contact hole formed in the overcoat layer 115, and may be electrically connected to a second electrode 125 of the first light-emitting element LED through a second connection electrode CE2 described later.

An adhesive layer 116 may be provided on the plurality of reflection electrodes RE substantially all over the substrate 110 to fix the first light-emitting element LED placed on the adhesive layer 116. The adhesive layer 116 may be formed of a photocurable adhesive material that can be cured by light. For example, the adhesive layer 116 may be formed of an acrylic-based material including a photosensitive agent, but embodiments of the present disclosure are not limited thereto.

A plurality of first light-emitting elements LED may be provided on the adhesive layer 116 in the plurality of sub-pixels SP, respectively. The plurality of first light-emitting elements LED are elements that emit light by current, and may include first light-emitting elements LED that emit red light, green light, blue light, etc., and a combination of these may implement various colors of light including white. For example, the plurality of first light-emitting elements LED may be a light-emitting diode (LED) or a micro LED, but embodiments of the present disclosure are not limited thereto.

The first light-emitting element LED may include a first semiconductor layer 121, a first light-emitting layer 122, a second semiconductor layer 123, the first electrode 124, the second electrode 125, and a passivation layer (not shown).

The first semiconductor layer 121 may be disposed on the adhesive layer 116, and the second semiconductor layer 123 may be disposed on the first semiconductor layer 121. The first semiconductor layer 121 and the second semiconductor layer 123 may be layers formed by doping n-type and p-type impurities into a specific material, respectively. For example, the first semiconductor layer 121 and the second semiconductor layer 123 may be layers in which n-type or p-type impurities are doped into a material such as gallium nitride (GaN), indium aluminum phosphide (InAlP), gallium arsenide (GaAs), and the like, respectively. In addition, the p-type impurities may be magnesium, zinc (Zn), beryllium (Be), and the n-type impurities may be silicon (Si), germanium (Ge), tin (Sn), and the like, but are not limited thereto.

A portion of the first semiconductor layer 121 may be disposed to protrude outside the second semiconductor layer 123. The first light-emitting element LED may be a lateral light-emitting element in which the upper surface of the first semiconductor layer 121 includes a portion overlapping the lower surface of the second semiconductor layer 123 and a portion disposed outside the lower surface of the second semiconductor layer 123. However, the size and shape of the first semiconductor layer 121 and the second semiconductor layer 123 may be modified in various ways and are not limited thereto.

The first light-emitting layer 122 may be disposed between the first semiconductor layer 121 and the second semiconductor layer 123. The first light-emitting layer 122 may receive electrons and holes from the first semiconductor layer 121 and the second semiconductor layer 123, respectively, to emit light.

The first light-emitting layer 122 may be formed of a single-quantum well (SQW) or multi-quantum well (MQW) structure, and, for example, may be formed of indium gallium nitride (InGaN) or gallium nitride (GaN), but embodiments of the present disclosure are not limited thereto.

The first electrode 124 may be disposed on the first semiconductor layer 121. The first electrode 124 may be an electrode for electrically connecting the driving transistor DT and the first semiconductor layer 121. In this case, the first semiconductor layer 121 may be a semiconductor layer doped with n-type impurities, and the first electrode 124 may be a cathode. The first electrode 124 may be disposed on the upper surface of the first semiconductor layer 121 exposed from the first light-emitting layer 122 and the second semiconductor layer 123. The first electrode 124 may be formed of a conductive material, for example, a transparent conductive material such as ITO (indium tin oxide) or IZO (indium zinc oxide) or an opaque conductive material such as titanium (Ti), gold (Au), silver (Ag), copper (Cu), or an alloy thereof, but embodiments of the present disclosure are not limited thereto.

The second electrode 125 may be disposed on the second semiconductor layer 123. The second electrode 125 may be disposed on the upper surface of the second semiconductor layer 123. In this case, since the second semiconductor layer 123 is disposed on the first semiconductor layer 121, the second electrode 125 disposed on the upper surface of the second semiconductor layer 123 may be placed at a higher position than the first electrode 124 disposed on the upper surface of the first semiconductor layer 121. The second electrode 125 may be an electrode for electrically connecting the power line VDD and the second semiconductor layer 123. In this case, the second semiconductor layer 123 may be a semiconductor layer doped with p-type impurities, and the second electrode 125 may be an anode. The second electrode 125 may be formed of a conductive material, for example, a transparent conductive material such as ITO (indium tin oxide) or IZO (indium zinc oxide) or an opaque conductive material such as titanium (Ti), gold (Au), silver (Ag), copper (Cu), or an alloy thereof, but embodiments of the present disclosure are not limited thereto.

Next, the passivation layer (not shown) may be disposed to partially surround the first semiconductor layer 121, the first light-emitting layer 122, the second semiconductor layer 123, the first electrode 124, and the second electrode 125. The passivation layer may be formed of an insulating material and can protect the first semiconductor layer 121, the first light-emitting layer 122, the second semiconductor layer 123, the first electrode 124, and the second electrode 125. In addition, contact holes exposing the first electrode 124 and the second electrode 125 may be formed in the passivation layer, so that the first connection electrode CE1 and the second connection electrode CE2 to be formed later can be electrically connected to the first electrode 124 and the second electrode 125 through the contact holes.

A first planarization layer 117a may be provided on the adhesive layer 116. The first planarization layer 117a may be placed to surround a portion of the side surface of a plurality of first light-emitting elements LED, thereby fixing and protecting the plurality of first light-emitting elements LED.

The first planarization layer 117a may be a single layer or multiple layers, and for example, may be formed of a photoresist or an acrylic-based organic material, but embodiments of the present disclosure are not limited thereto.

Meanwhile, the height of the first planarization layer 117a may be lower than the height of the first electrode 124. For example, the thickness of the first planarization layer 117a may be adjusted by performing an ashing process. For example, after applying a material layer of the first planarization layer 117a to cover the first light-emitting element LED, the ashing process may be performed to reduce the overall thickness of the material layer of the first planarization layer 117a, so that the height of the first planarization layer 117a may be formed lower than the height of the first electrode 124. Thus, the first planarization layer 117a may expose the first electrode 124. Accordingly, the first connection electrode CE1 disposed on the first planarization layer 117a can be easily connected to the first electrode 124 without a separate contact hole.

The first connection electrode CE1 may be disposed on the first planarization layer 117a. The first connection electrode CE1 may be an electrode arranged in each of the plurality of sub-pixels SP to electrically connect the first light-emitting element LED and the driving transistor DT. The first connection electrode CE1 may be connected to the first reflection electrode RE1 through a contact hole formed in the first planarization layer 117a and the adhesive layer 116. Accordingly, the first connection electrode CE1 may be electrically connected to one of the source electrode SE and the drain electrode DE of the driving transistor DT through the first reflection electrode RE1. For example, the first connection electrode CE1 may connect the first electrode 124 of the first light-emitting element LED to the source electrode SE of the driving transistor DT, but embodiments of the present disclosure are not limited thereto.

Meanwhile, the first connection electrode CE1 may be formed by providing a material layer of the first connection electrode CE1 to cover the first light-emitting element LED and then removing a portion of the material layer of the first connection electrode CE1 disposed on the upper surface and a part of the side surface of the second semiconductor layer 123 and the second electrode 125. For example, after photoresist is applied on the first light-emitting element LED, the second electrode 125 may be exposed by removing the photoresist disposed on the upper surface of the second electrode 125 and the upper surface and the part of the side surface of the second semiconductor layer 123 through an ashing process. Thus, only the portion of the material layer of the first connection electrode CE1 disposed on the upper surface of the second electrode 125 and the upper surface and the part of the side surface of the second semiconductor layer 123 may be exposed. In addition, the first connection electrode CE1 may be formed by removing the exposed material layer of the first connection electrode CE1 through the ashing process, but embodiments of the present disclosure are not limited thereto.

A second planarization layer 117b may be provided on the first planarization layer 117a and the plurality of first connection electrodes CE1. The second planarization layer 117b may flatten the upper surface of the substrate 110 on which the first light-emitting element LED is disposed, together with the first planarization layer 117a and may fix the first light-emitting element LED on the substrate 110 together with the adhesive layer 116.

In addition, the second planarization layer 117b may be disposed to cover the first connection electrode CE1, thereby allowing the first connection electrode CE1 and the second connection electrode CE2 to be separated from each other. Accordingly, the short circuit between the first connection electrode CE1 and the second connection electrode CE2 may be prevented.

For example, only the second planarization layer 117b may be disposed between the first connection electrode CE1 and the second connection electrode CE2. The second planarization layer 117b may be a single layer, and, for example, may be formed of photoresist or acrylic-based organic material, but is not limited thereto.

The second connection electrode CE2 may be provided on the second planarization layer 117b. The second connection electrode CE2 may be an electrode for electrically connecting the first light-emitting element LED and the power line VDD. The second connection electrode CE2 may be connected to the second reflection electrode RE2 through a contact hole formed in the second planarization layer 117b, the first planarization layer 117a, and the adhesive layer 116. Accordingly, the second connection electrode CE2 may be electrically connected to the power line VDD through the second reflection electrode RE2. For example, the second connection electrode CE2 may connect the second electrode 125 of the first light-emitting element LED to the power line VDD, but embodiments of the present disclosure are not limited thereto.

The second connection electrode CE2 disposed on the second planarization layer 117b may be formed on the first light-emitting element LED and may be arranged to distinguish the emission area EA and the non-emission area NEA. That is, the second connection electrode CE2 may include a first portion corresponding to the non-emission area NEA and a second portion corresponding to the emission area EA. The first portion may include a plurality of layers in the non-emission area NEA, and the second portion may be disposed over the first light-emitting element LED and connected to the first light-emitting element LED. The emission area EA may be an area where light emitted from the first light-emitting layer 122 of the first light-emitting element LED is outputted to the outside of the display device 100, and the non-emission area NEA may be an area where light emitted from the first light-emitting layer 122 of the first light-emitting element LED is blocked by the second connection electrode CE2 and is not outputted to the outside.

The second connection electrode CE2 may include a transparent electrode TC in the emission area EA. The transparent electrode TC may be formed of a transparent conductive material or may be a single layer of a transparent conductive material. Light emitted from the first light-emitting layer 122 of the first light-emitting element LED may be outputted to the outside of the display device 100 in the emission area EA through the transparent electrode TC. The transparent electrode TC may be formed of a transparent conductive material composed of oxide materials including indium (In) such as indium tin oxide (ITO) or indium zinc oxide (IZO), but embodiments of the present disclosure are not limited thereto.

The second connection electrode CE may include the transparent electrode TC and an antireflection layer on the transparent electrode TC in the non-emission area NEA.

The non-emission area NEA may be an area where light emitted from the first light-emitting layer 122 of the first light-emitting element LED is not outputted to the outside. Typically, there may be a method of preventing light from being emitted to the outside by using a reflection layer with relatively high reflectance to reflect the emitted light inward. When the reflection layer with relatively high reflectance is applied to the non-emission area NEA, light emitted from the inside of the display device 100 can be blocked, but light from the outside of the display device 100 may also be reflected at the same time, which causes a problem of lowering the quality of the display device 100. In this case, the second connection electrode CE2 may be an electrode for electrically connecting the first light-emitting element LED and the power line VDD. Since it is necessary to electrically connect the power line VDD disposed in the non-emission area NEA and the first light-emitting element LED disposed in the emission area EA, the transparent electrode TC of the second connection electrode CE2 disposed in the emission area EA may extend into the non-emission area NEA, the second connection electrode CE2 may further include multiple layers AR1 and AR2 on the transparent electrode TC in the non-emission area NEA.

In the non-emission area NEA, the antireflection layer disposed on the transparent electrode TC may include the multiple layers. The antireflection layer may include a first antireflection layer AR1 and a second antireflection layer AR2. As will be described later, the antireflection layer may appear black in various ways in an area corresponding to the non-emission area NEA, and an area where such an antireflection layer is formed may form an antireflection area. The first antireflection layer AR1 may be a reflection layer formed of a conductive material having relatively high light reflectance and high electrical conductivity, and the second antireflection layer AR2 may be a semitransparent film formed of an oxide or a nitride. The first antireflection layer AR1 may be formed of a metal material such as copper (Cu), aluminum (Al), silver (Ag), or gold (Au), and the second antireflection layer AR2 may be formed of an oxide or a nitride of a metal material such as molybdenum (Mo), titanium (Ti), or chromium (Cr). For example, the light transmittance of the second antireflection layer AR2 may be higher than the light transmittance of the first antireflection layer AR1 and lower than the light transmittance of the transparent electrode TC.

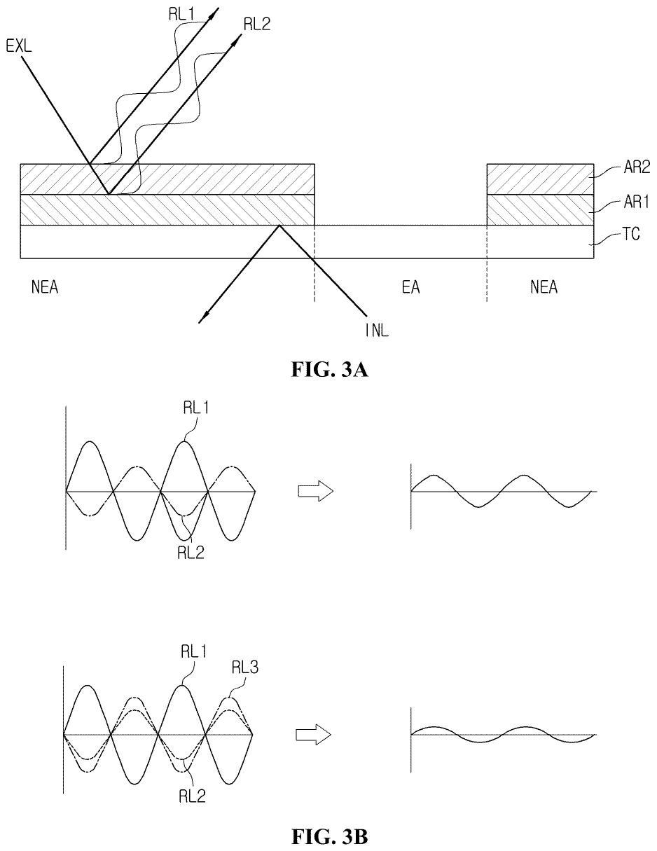

FIG. 3A and FIG. 3B are views showing cases where external incident light EXL and internal incident light INL are reflected by the second connection electrode CE2. In this case, the external incident light EXL may be light such as sunlight or fluorescent light coming from the outside of the display device 100 toward the display device 100, and the internal incident light INL may be light emitted from the first light-emitting layer 122 of the first light-emitting element LED.

In FIG. 3A, the internal incident light INL, i.e., light emitted from the first light-emitting element LED, may pass through the transparent electrode TC in the emission area EA, so that light is outputted to the outside of the display device 100. However, in the non-emission area NEA, the internal incident light INL may be reflected back into the display device 100 by the first antireflection layer AR1, which is a reflection layer with relatively high light reflectance, and in this case, a partition wall (not shown) and a reflector (not shown) may be provided around the first light-emitting element LED to emit light to the outside of the display device 100, thereby improving the light extraction efficiency of the first light-emitting element LED.

The external incident light EXL may travel from the outside to the display device 100 and may be reflected at the second connection electrode CE2. Since light is reflected at the interface of two objects having different refractive indexes, in two layers of FIG. 3A, some of the external incident light EXL may be first reflected at the surface of the second antireflection layer AR2 to generate a first reflected light RL1, and the rest of the external incident light EXL passing through the second antireflection layer AR2 without being reflected may be completely reflected at the interface of the first antireflection layer AR1 and the second antireflection layer AR2 to generate a second reflected light RL2, thereby generating two types of reflected lights RL1 and RL2. At this time, the phases of the first reflected light RL1 and the second reflected light RL2 may be different due to the difference in the optical path, and these two reflected lights RL1 and RL2 may be combined to cause destructive interference. In this case where destructive interference occurs, the amplitude of the reflected light may be reduced compared to the first reflected light RL1 and the second reflected light RL2, thereby reducing the reflected light. In the case where the antireflection layer is configured as a double layer as shown in FIG. 3A, the second connection electrode CE2 may be configured as a triple layer of semitransparent film-reflective film-transparent film in the direction from the outside of the display device 100 to the substrate 110 in the non-emission area NEA so that the reflected light may be effectively reduced. In the above configured, the transparent film under the reflective film may be configured as the transparent electrode TC. By configuring the second connection electrode CE2 as shown in FIG. 3A, the internal incident light INL can be limited to the emission area EA, thereby preventing color mixing between sub-pixels SP of different colors. For the external incident light EXL, by reducing the reflected light using the destructive interference of the first reflected light RL1 and the second reflected light RL2, the quality of the display device 100 can be improved.

This kind of reflection of the multiple layers may be a phenomenon that generally occurs in two or more layers. The upper drawing of FIG. 3B shows a configuration in which the second connection electrode CE2 is a triple layer where the reflection described in FIG. 3A occurs in the double layer. The lower drawing of FIG. 3B compares the cases in which the reflection occurs in the double layer and the triple layer. For the external incident light EXL, in the case where a third reflected RL3 is generated due to an additional layer in addition to the first reflected light RL1 and the second reflected light RL2, if the phase difference of the reflected lights is adjusted, the reflected light can be reduced more significantly than the reduction by the reflection in two layers due to the destructive interference of multiple reflections. In order to implement the high-quality display device 100 for the external incident light EXL, the reflection layer, beneficially, can be configured as a combination of a transparent film-semitransparent film or a semitransparent film-transparent film having different refractive indexes at the boundary thereof, which is more effective than multiple reflection layers. Since the internal incident light INL has to be totally reflected at the lowest layer of the layers to have full reflection, the reflection layer of the second connection electrode CE2 may include a combination of a transparent film-semitransparent film-reflective film or a semitransparent film-transparent film-reflective film. Since the second connection electrode CE2 is formed to include the transparent electrode TC extending from the emission area EA to the non-emission area NEA, the second connection electrode CE2 may be configured as a quadruple-layer of transparent film-semitransparent film-reflective film-transparent film or semitransparent film-transparent film-reflective film-transparent film including the triple-layer of transparent film-semitransparent film-reflective film or semitransparent film-transparent film-reflective film in the direction from the outside of the display device 100 to the substrate 110 in the non-emission area NEA. In the above configuration, the transparent film under the reflective film may be composed of the transparent electrode TC. In this case, the second antireflection layer AR2 may be configured as the multiple layers and may include a transparent film-semitransparent film or a semitransparent film-transparent film having different refractive indexes. The second antireflection layer AR2 may include a metal material such as molybdenum, titanium, or chromium, but is not limited thereto, and may further include an inorganic oxide or nitride such as silicon oxide or silicon nitride.

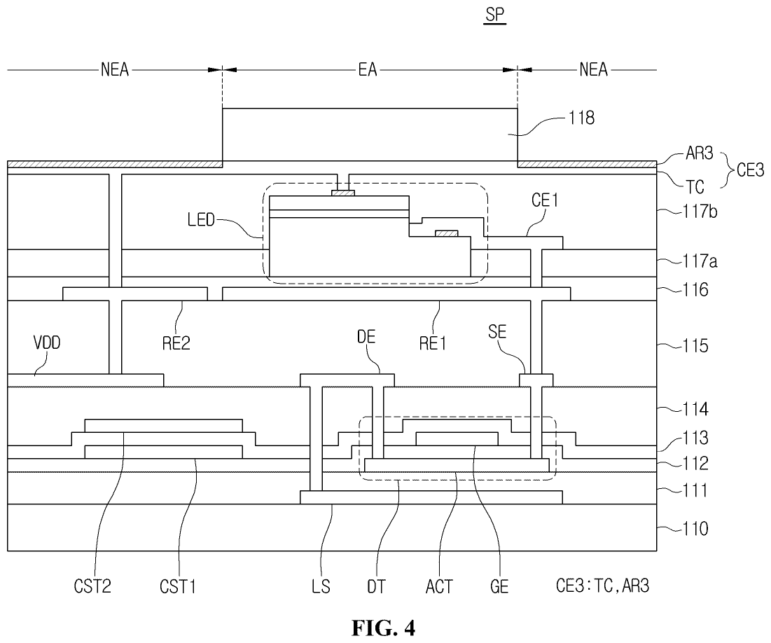

FIG. 4 is a cross-sectional view illustrating each sub-pixel of a display panel of a display device according to a second embodiment of the present disclosure, and descriptions of parts that are the same as those of the first embodiment will be omitted.

A third connection electrode CE3 may be disposed on the second planarization layer 117b and may electrically connect the first light-emitting element LED and the power line VDD. The third connection electrode CE3 disposed on second planarization layer 117b may be formed on the first light-emitting element LED and may be arranged to distinguish the emission area EA and the non-emission area NEA. The third connection electrode CE may include the transparent electrode TC in the emission area EA, and a first transparent film 118 may be disposed on the transparent electrode TC. The first transparent film 118 may be an inorganic insulation layer formed of a transparent inorganic material, and light emitted from the first light-emitting layer 122 of the first light-emitting element LED may be outputted to the outside of the display device 100 passing through the transparent electrode TC and the first transparent film 118 in the emission area EA. The first transparent film 118 may be an inorganic insulation layer formed of an inorganic oxide or nitride such as silicon oxide or silicon nitride having an inorganic component, but is not limited thereto.

In order to prevent light emitted from the first light-emitting element LED from being outputted to the outside in the non-emission area NEA and to prevent reflection of light coming from the outside of the display device 100, the third connection electrode CE may include third antireflection layer AR3 on the transparent electrode TC in the non-emission area NEA. The third antireflection layer AR3 may be formed of a black film and absorb light emitted from the first light-emitting element LED to prevent the light from being emitted to the outside, and effectively reduce reflection of light coming from the external light. In the non-emission area NEA, the first transparent film 118, which is disposed in the emission area EA, may not be disposed on the third antireflection layer AR3 of the third connection electrode CE3.

The transparent electrode TC and the third antireflection layer AR3 of the third connection electrode CE3 formed in the non-emission area NEA may include the same components. Since the transparent electrode TC is arranged to extend from the emission area EA, the transparent electrode TC of the third connection electrode CE3 of the emission area EA and the third antireflection layer AR3 of the non-emission area NEA may include the same components. As described below, the third antireflection layer AR3 may be arranged together with the transparent electrode TC and may change in component ratios through the process, thereby changing into a discoloration layer that appears black. This change in component ratios may occur when the transparent electrode TC is reduced in the etching process, so that the transparent electrode TC and the third antireflection layer AR3 may include the same components but have different component ratios. At this time, the components whose ratio changes in the transparent electrode TC and third antireflection layer AR3 may be indium and oxygen. That is, the ratio of indium and oxygen may be different in transparent electrode TC and third antireflection layer AR3.

For example, after forming the transparent electrode TC on the second planarization layer 117b in the emission area EA and the non-emission area NEA, the first transparent film 118 may be formed only in the emission area EA. After forming the first transparent film 118, the transparent electrode TC and the first transparent film 118 may be disposed in the emission area EA, and the transparent electrode TC may be disposed in the non-emission area NEA. Thereafter, when the etching process is performed, the surface portion of the transparent electrode TC exposed in the non-emission area NEA may react with the gas used in the etching process to cause an oxidation or reduction reaction. At this time, the indium component of the transparent electrode TC may be precipitate, and the surface portion of the transparent electrode where the component has changed may change into the third antireflection layer AR3, which is a discoloration layer with a black color. In the non-emission area NEA, some of the transparent electrode TC may change into the third antireflection layer AR3, which may be formed to be in contact with the rest of the transparent electrode TC that has not changed. At this time, the etching process may be a dry etching process, and the gas used in the etching process may include hydrogen gas. In the etching process using hydrogen plasma, the indium oxide on the surface of the third antireflection layer AR3 may react with hydrogen to cause a reduction reaction, so that the surface portion of the transparent electrode TC may change into the third antireflection layer TC with the black color and the surface roughness of the third antireflection layer AR3 may deteriorate. At this time, since the first transparent film 118 is formed on the transparent electrode TC of the third connection electrode CE3 in the emission area EA, when the etching process is performed, the transparent electrode TC of the emission area EA may be protected by the first transparent film 118, thereby preventing the etching reaction from occurring. In this case, the transparent electrode TC of the emission area EA and the third antireflection layer AR3 of the non-emission area NEA may contain the same components, but the component ratios may be different. The components whose ratios are different may be the ratio of indium and oxygen. In addition, the surface portion of the transparent electrode TC under the first transparent film 118 in the emission area EA and the third antireflection layer AR3 in the non-emission area NEA may have different surface roughnesses. For example, the surface roughness value of the third antireflection layer AR3 in the non-emission area NEA may be greater than the surface roughness value of the surface portion of the transparent electrode TC under the first transparent film 118 in the emission area EA.

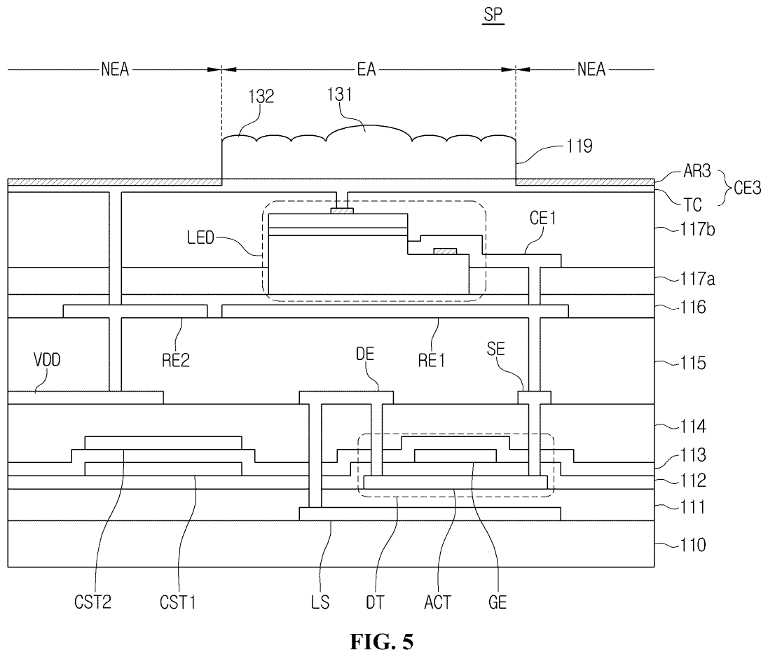

FIG. 5 is a cross-sectional view illustrating each sub-pixel of a display panel of a display device according to a third embodiment of the present disclosure, and descriptions of parts that are the same as those of the second embodiment will be omitted.

In the second embodiment of FIG. 4, the first transparent film 118 on the transparent electrode TC of the emission area EA may be configured as a flat film. However, in the third embodiment of FIG. 5, a second transparent film 119 may be disposed on the transparent electrode TC of the emission area EA, and the second transparent film 119 may be configured in a plurality of lens shapes. The second transparent film 119 may be an inorganic insulating layer formed of a transparent inorganic material, and light emitted from the first light-emitting layer 122 of the first light-emitting element LED may be outputted to the outside of the display device 100 passing through the transparent electrode TC and the second transparent film 119 in the emission area EA. The second transparent film 119 may be formed of an inorganic oxide or nitride such as silicon oxide or silicon nitride, but is not limited thereto.

The surface portion of the second transparent film 119 may be configured with a plurality of lens shapes on the transparent electrode TC in the emission area EA, so that light emitted from the first light-emitting layer 122 of the first light-emitting element LED may be configured to be more uniformly emitted based on the center of the emission area EA. The second transparent film 119 may be configured symmetrically with respect to the center of the emission area EA, and a first lens 131 disposed in the center of the emission area EA may have a convex shape and may serve to focus the light emitted from the first light-emitting layer 122 of the first light-emitting element LED toward the center of the emission area EA. Second lenses 132 configured to surround the first lens 131 may be configured in a convex shape and may be configured to have a smaller size than the first lens 131. The second lenses 132 may be configured in plural and may be disposed on the surface portion of the second transparent film 119. The second transparent film 119 may include the first lens 131 having a relatively large lens shape at the center of the emission area EA and the second lenses 132 surrounding the first lens 131 and having the smaller size than the first lens 131 in the emission area EA. Thus, when the first light-emitting layer 122 of the first light-emitting element LED emits non-uniform or when the first light-emitting element LED is not placed at the center of the emission area EA and the light emitted from the first light-emitting layer 122 is more in the periphery than in the center of the emission area EA, the first lens 131 and the second lenses 132 can be configured to compensate for this and make the light come out more uniformly based on the center of the emission area EA.

In the first, second, and third embodiments of FIG. 2, FIG. 4, and FIG. 5, the first light-emitting element LED may be a lateral type light-emitting diode as an example, but is not limited thereto, and may also be configured to use a vertical type light-emitting diode. In addition, the first light-emitting element LED may be configured to use an organic light-emitting diode.

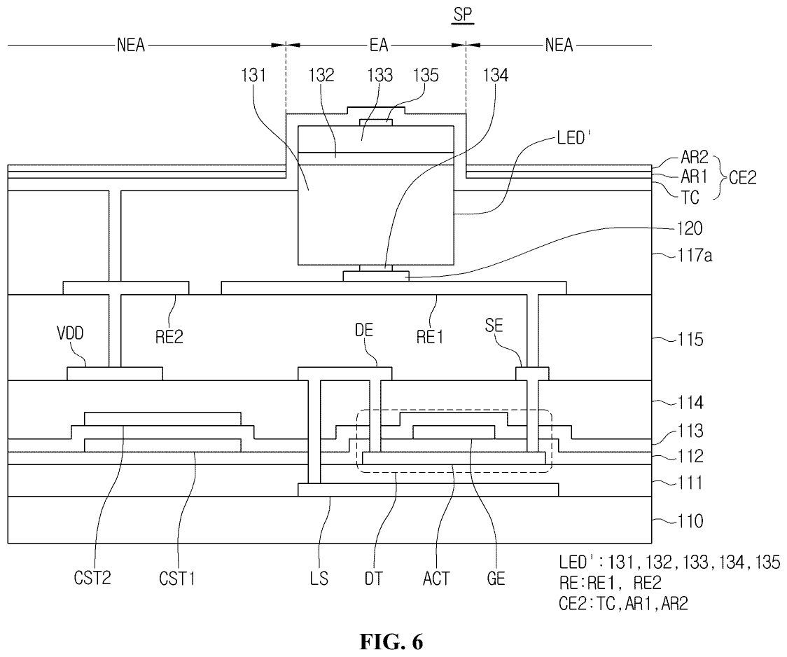

FIG. 6 is a cross-sectional view illustrating each sub-pixel of a display panel of a display device according to a fourth embodiment of the present disclosure, and descriptions of parts that are the same as those of the first embodiment of FIG. 2 will be omitted.

In the first embodiment of FIG. 2, a lateral type light-emitting diode may be used as the light-emitting element, but in the fourth embodiment of FIG. 6, a vertical type light-emitting diode may be used as the light-emitting element and it not limited thereto.

Referring to FIG. 6, the light-shielding pattern LS, the driving transistor DT, the buffer layer 111, the gate insulation layer 112, the first interlayer insulation layer 113, the second interlayer insulation layer 114, the overcoat layer 115, the first capacitor electrode CST1, the second capacitor electrode CST2, the power line VDD, the first reflection electrode RE1, and the second reflection electrode RE2 may be provided in each sub-pixel SP on the substrate 110 and may be connected in the same manner as in FIG. 2.

An electrode connection layer 120 may be formed on the plurality of reflection electrodes RE to fix a second light-emitting element LED′ disposed on the electrode connection layer 120. The electrode connection layer 120 may be electrically connected to the first reflection electrode RE1 and may be electrically connected to a third electrode 134 of the second light-emitting element LED'. Through this, the electrode connection layer 120 may be arranged in each of the plurality of sub-pixels SP and may electrically connect the second light-emitting element LED′ and the driving transistor DT. The electrode connection layer 120 may include a thermosetting adhesive material that can be cured by heat, and may further include a metal material such as indium so as to be electrically connected to the first reflection electrode RE1 and the third electrode 134.

A plurality of second light-emitting elements LED′ may be provided on the electrode connection layer 120 in the plurality of sub-pixels SP, respectively. The plurality of second light-emitting elements LED′ are elements that emit light by current, and may include second light-emitting elements LED′ that emit red light, green light, blue light, etc., and a combination of these may implement various colors of light including white. For example, the plurality of second light-emitting elements LED′ may be a light-emitting diode (LED) or a micro LED, but embodiments of the present disclosure are not limited thereto.

The second light-emitting element LED′ may include a third semiconductor layer 131, a second light-emitting layer 132, a fourth semiconductor layer 133, the third electrode 134, the fourth electrode 135, and a passivation layer (not shown). The components and roles of the third semiconductor layer 131, the second light-emitting layer 132, the fourth semiconductor layer 133, the third electrode 134, and the fourth electrode 135 may be substantially the same as those of the first semiconductor layer 121, the first light-emitting layer 122, the second semiconductor layer 123, the first electrode 124, and the second electrode 125 of FIG. 2, respectively, and thus, descriptions of the same parts may be omitted.

The first planarization layer 117a may be provided on the overcoat layer 115 and the reflection electrodes RE. The first planarization layer 117a may be placed to surround a portion of the side surface of a plurality of second light-emitting elements LED′, thereby fixing and protecting the plurality of second light-emitting elements LED′. The upper surface of the first planarization layer 117a may be positioned lower than the second light-emitting layer 132 and may not surround the second light-emitting layer 132. However, embodiments of the present disclosure are not limited thereto.

The second connection electrode CE2 may be provided on the first planarization layer 117a. The second connection electrode CE2 may be an electrode for electrically connecting the second light-emitting element LED′ and the power line VDD. The second connection electrode CE2 may be connected to the second reflection electrode RE2 through a contact hole formed in the first planarization layer 117a. Accordingly, the second connection electrode CE2 may be electrically connected to the power line VDD through the second reflection electrode RE2.

The second connection electrode CE2 disposed on the first planarization layer 117a may be formed on the second light-emitting element LED′ and may be arranged to distinguish the emission area EA and the non-emission area NEA. That is, the second connection electrode CE2 may include a first portion corresponding to the non-emission area NEA and a second portion corresponding to the emission area EA. The first portion may include a plurality of layers in the non-emission area NEA, and the second portion may be disposed over the second light-emitting element LED′ and connected to the second light-emitting element LED′. The emission area EA may be an area where light emitted from the second light-emitting layer 132 of the second light-emitting element LED′ is outputted to the outside of the display device 100, and the non-emission area NEA may be an area where some of light emitted from the second light-emitting layer 132 of the second light-emitting element LED′ toward the reflection electrode RE is reflected by the reflection electrode RE and blocked by the second connection electrode CE2, thereby not being outputted to the outside.

The second connection electrode CE2 may include the transparent electrode TC in the emission area EA. The transparent electrode TC may include a transparent conductive material. In the non-emission area NEA, the second connection electrode CE2 may include the transparent electrode TC, and the antireflection layer composed of multiple layers may be provided on the transparent electrode TC. The antireflection layer may include the first antireflection layer AR1 and the second antireflection layer AR2. The first antireflection layer AR1 may be a reflection layer formed of a conductive material having relatively high light reflectance and high electrical conductivity, and the second antireflection layer AR2 may be a semitransparent film formed of an oxide or a nitride.

By including the first antireflection layer AR1 having relatively high light reflectance, the antireflection layer disposed on the transparent electrode TC in the non-emission area NEA may prevent some of light emitted from the second light-emitting layer 132 of the second light-emitting element LED′ toward the reflection electrode RE from being outputted to the outside in the non-emission area NEA after being reflected by the reflection electrode RE. By preventing light reflection by the reflection electrode RE, the difference in brightness according to the viewing angle due to the positional deviation of the second light-emitting element LED′ on the reflection electrode RE can be reduced or improved.

In the non-emission area NEA, the antireflection layer may be configured to be positioned lower than the top of the second light-emitting element LED′ so as to be in contact with the second light-emitting element LED′ and to surround the side surface of the second light-emitting element LED′. The top of the first planarization layer 117a may be positioned lower than the second light-emitting layer 132, and the antireflection layer may be positioned lower than the second light-emitting layer 132, i.e., the second light-emitting layer 132 may be positioned higher than the antireflection layer. Through this arrangement, light from the second light-emitting layer 132 that is in the opposite direction to the reflection electrode may not be restricted. Light from the second light-emitting layer 132 that is in direction of the reflection electrode may be reflected by the reflection electrode and may be emitted to the emission area EA, thereby improving the light extraction efficiency, and some of the light reflected by the reflection electrode toward the non-emission area NEA may be blocked. However, embodiments of the present disclosure are not limited thereto.

The antireflection layer may include the first antireflection layer AR1 and the second antireflection layer AR2, and as described in FIG. 3A and FIG. 3B, by reducing the reflected light through the destructive interference of the external light directed from the outside of the display device to the substrate, the quality of the display device 100 may be improved.

According to embodiments of the present disclosure, a low-cost and high-quality display device can be provided by configuring the light-emitting element and the second connection electrode connected to the light-emitting element and distinguishing the emission area and the non-emission area.

The display device according to various embodiments of the present disclosure can be described as follows.

A display device according to various embodiments of the present disclosure comprises a substrate including a display area, a driving element formed over the substrate, a first connection electrode connected to the driving element, a light-emitting element connected to the first connection electrode, and a second connection electrode connected to the light-emitting element and distinguishing an emission area and a non-emission area. The second connection electrode can include an antireflection area appearing black in the non-emission area, and can include a plurality of layers in the antireflection area.

In the display device according to various embodiments of the present disclosure, the second connection electrode can be formed over the light-emitting element and connected to the light-emitting element.

In the display device according to various embodiments of the present disclosure, the second connection electrode can include a transparent conductive material, and the second connection electrode can be configured as a single layer of the transparent conductive material in the emission area.

In the display device according to various embodiments of the present disclosure, the second connection electrode of the non-emission area can include an antireflection layer composed of multiple layers having conductivity, and the transparent conductive material of the emission area can extend into the non-emission area and disposed under the antireflection layer composed of the multiple layers.

In the display device according to various embodiments of the present disclosure, the antireflection layer of the non-emission area can minimize reflection of external light by offsetting light due to difference in refractive index between the multiple layers.

In the display device according to various embodiments of the present disclosure, the antireflection layer of the second connection electrode can include a double layer of semitransparent film-reflective film or a triple layer of semitransparent film-transparent film-reflective film in the direction from the outside of the display device toward the substrate.

In the display device according to various embodiments of the present disclosure, the semitransparent film of the antireflection layer of the second connection electrode can be an oxide of one of chromium, molybdenum, titanium, and aluminum, and the reflective film can include one of copper, aluminum, silver, and gold.

In the display device according to various embodiments of the present disclosure, the top of the light-emitting element can be positioned higher than the antireflection layer of the second connection electrode.

In the display device according to various embodiments of the present disclosure, a planarization layer can be disposed over the driving element and surround the light-emitting element, and the top of the planarization layer can be positioned lower than the light-emitting layer of the light-emitting element.

In the display device according to various embodiments of the present disclosure, an inorganic insulation layer can be disposed on and be in contact with the second connection electrode in the emission area, and an inorganic insulation layer may not be disposed on the second connection electrode in the non-emission area.

In the display device according to various embodiments of the present disclosure, the transparent conductive material of the emission area where the inorganic insulation layer is disposed and the antireflection layer of the non-emission area can have the same components, the component ratios can be different, and the different component ratios can be component ratios of indium and oxygen.

In the display device according to various embodiments of the present disclosure, the antireflection layer of the second connection electrode can appear black.

In the display device according to various embodiments of the present disclosure, the distinction of the second connection electrode between the emission area and the non-emission area can be formed through the following steps. A driving element can be formed over a substrate. A first connection electrode can be formed over and connected to the driving element. A light-emitting element can be formed over the first connection electrode. A second connection electrode formed of a transparent conductive material including indium can be deposited over the light-emitting element, and an inorganic insulation layer can be formed only in the emission area on the deposited second connection electrode. An etching process such as a plasma process containing hydrogen can be performed on the second connection electrode of the non-emission area using the inorganic insulation layer as a mask, so that a part of the second connection electrode of the non-emission area can change from a transparent color to black and become a discoloration layer.

In the display device according to various embodiments of the present disclosure, the upper surface of the inorganic insulation layer on the second connection electrode of the emission area can have a flat shape or include a lens shape.

In the display device according to various embodiments of the present disclosure, when the upper surface of the inorganic insulation layer on the second connection electrode of the emission area includes a lens shape, the lens shape can include a first lens and second lenses having a smaller size than the first lens. The first lens can be disposed in a center of the emission area, and the second lenses can surround the first lens. The lens shape can be configured to be symmetrical with respect to the center of the emission area.

According to embodiments of the present disclosure, since the emission area and the non-emission area can be distinguished only by the second connection electrode on the light-emitting element, a separate film for preventing reflection of external light is not necessary, an thus a low-cost and high quality display device with low reflectance can be provided.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display device, comprising:
a substrate including an emission area and a non-emission area;
a driving element formed over the substrate;
a first connection electrode connected to the driving element;
a light-emitting element connected to the first connection electrode; and
a second connection electrode formed over the light-emitting element,
wherein the second connection electrode includes an antireflection area corresponding to the non-emission area, and
wherein a first portion of the second connection electrode includes a plurality of layers in the antireflection area to distinguish the emission area and the non-emission area.

2. The display device of claim 1, wherein a second portion of the second connection electrode is disposed over the light-emitting element and is connected to the light-emitting element.

3. The display device of claim 1, wherein the second connection electrode includes a transparent conductive material.

4. The display device of claim 3, wherein the second connection electrode is configured as a single layer of the transparent conductive material in the emission area.

5. The display device of claim 4, wherein in the second connection electrode, a part of the single layer in the emission area is arranged to extend to the antireflection area, and an antireflection layer is disposed on the single layer in the antireflection area.

6. The display device of claim 5, wherein the antireflection layer of the second connection electrode appears black.

7. The display device of claim 5, wherein the antireflection layer includes multiple layers having conductivity.

8. The display device of claim 7, wherein the antireflection layer minimizes reflection of external light by offsetting light due to difference in refractive index between the multiple layers.

9. The display device of claim 7, wherein the antireflection layer of the second connection electrode includes a double layer of semitransparent film-reflective film or a triple layer of semitransparent film-transparent film-reflective film.

10. The display device of claim 9, wherein the semitransparent film is an oxide of one of chromium, molybdenum, titanium, and aluminum, and the reflective film includes one of copper, aluminum, silver, and gold.

11. The display device of claim 3, wherein an inorganic insulation layer is disposed on and is in contact with the second connection electrode in the emission area, and an inorganic insulation layer is not disposed on the second connection electrode in the non-emission area.

12. The display device of claim 5, wherein the antireflection layer is composed of a discoloration layer, and
wherein the single layer of the second connection electrode and the discoloration layer of the second connection electrode have same components, and component ratios of the single layer and the discoloration layer are different from each other.

13. The display device of claim 12, wherein the different component ratios of the single layer and the discoloration layer of the second connection electrode are component ratios of indium and oxygen.

14. The display device of claim 11, wherein an upper surface of the inorganic insulation layer has a flat shape.

15. The display device of claim 11, wherein an upper surface of the inorganic insulation layer includes a lens shape.

16. The display device of claim 15, wherein the lens shape of the inorganic insulation layer includes a first lens and second lenses having a smaller size than the first lens, and
wherein the first lens is disposed in a center of the emission area, and the second lenses surround the first lens.

17. The display device of claim 16, wherein the lens shape is configured to be symmetrical with respect to the center of the emission area.

18. The display device of claim 5, wherein the antireflection layer is positioned lower than a top of the light-emitting element and surrounds the light-emitting element.

19. The display device of claim 5, wherein the light-emitting element includes a light-emitting layer, and
wherein the light-emitting layer is positioned higher than the antireflection layer.

20. The display device of claim 1, further comprising a planarization layer over the driving element,
wherein the light-emitting element includes a light-emitting layer,
wherein the planarization layer surrounds the light-emitting element, and
wherein a top of the planarization layer is disposed lower than the light-emitting layer of the light-emitting element.
